(19) United States
(12) Patent Application Publication
(10) Pub. No.: US 2024/0097093 A1
(43) Pub. Date: Mar. 21, 2024

(54) ELECTRONIC DEVICES WITH IMPURITY GETTERING

(71) Applicant: GOOGLE llc, Mountain View, CA (US)

(72) Inventors: Tarek Suwwan de Felipe, Los Altos, CA (US); Li Yan, Dublin, CA (US)

(21) Appl. No.: 18/477,964

(22) Filed: Sep. 29, 2023

Related U.S. Application Data
(63) Continuation of application No. PCT/US2023/074312, filed on Sep. 15, 2023.
(60) Provisional application No. 63/376,025, filed on Sep. 16, 2022.

(51) Int. Cl. H01L 33/62; H01L 25/075; H01L 33/20; H01L 33/32

(52) U.S. Cl. CPC H01L 33/62; H01L 25/0753; H01L 33/20; H01L 33/325

(57) ABSTRACT

In a general aspect, an electronic device includes a semiconductor structure including a doped surface, a silver-based (Ag-based) layer electrically contacting at least a portion of the doped surface and a passivation layer disposed on a portion of the semiconductor structure. A portion of the passivation layer is in physical contact with the Ag-based layer. The passivation layer is a material compound including a II-Nitride material.

### CROSS REFERENCE TO RELATED APPLICATIONS

This application is a bypass continuation application of PCT Application No. PCT/US2023/074312, filed Sep. 15, 2023, which claims priority to U.S. Provisional Application 63/376,025, filed Sep. 16, 2022, the disclosures of which are incorporated herein by reference in their entireties.

### TECHNICAL FIELD

This disclosure relates to electronic devices and associated methods. For instance, this disclosure relates to semiconductor devices, such as micro-light-emitting diode (microLED) devices and related methods.

### BACKGROUND

Manufacturing of semiconductor devices can involve a complex sequence of processes (operations, etc.), Such processes can include thermal processes, chemical processes, etch processes, material deposition operations, material growth processes, implantation processes, etc. In some instance, an element or portion of a semiconductor device produced during one process can be adversely affected by a subsequent process. For example, light-emitting diodes LEDs), such microLEDs, that are produced using semiconductor manufacturing process can include metallic contact that provide both electrical connectivity for operation of an associated LED, as well as reflectivity for light-emitted by the LED, e.g., for optical operation of the LED. Such contacts can be adversely affected (e.g., degraded) by semiconductor processes that are performed subsequent to associated processes for producing the contacts. For instance, such subsequent manufacturing processes can degrade electrical performance (e.g., stability) and/or optical performance (e.g., reflectivity) associated of an LED, e.g., as a result of degradation of a contact (contact layer, reflective contact, etc.).

### SUMMARY

In a general aspect, an electronic device includes a semiconductor structure including a doped surface, a silver-based (Ag-based) layer electrically contacting at least a portion of the doped surface and a passivation layer disposed on a portion of the semiconductor structure. A portion of the passivation layer is in physical contact with the Ag-based layer. The passivation layer is a material compound including a II-Nitride material.

Implementations can include one or more of the following features or aspects, alone or in combination. For example, the doped surface can be at least one of a top surface of the semiconductor structure, or a surface of an epitaxial layer.

The semiconductor structure can include a sidewall surface. At least a portion of the passivation layer can be disposed on the sidewall surface.

A first portion of the Ag-based layer can be disposed on the doped surface. A second portion of the Ag-based layer can be disposed on the passivation layer.

The electronic device can have a lateral dimension of less than or equal to 10 micrometers (μm).

The semiconductor structure can include a III-Nitride material.

The II-Nitride material can include at least one of magnesium nitride, calcium nitride, or beryllium nitride.

The material compound can include a Group III element.

The passivation layer can include, by composition, at least ninety percent of the II-Nitride material.

The semiconductor structure can include a layer including gallium nitride (GaN), and a light-emitting layer including indium gallium nitride (InGaN).

The electronic device can be a light-emitting diode (LED). The LED can include a mesa with a top surface, a sidewall, and a base. The passivation layer can cover a portion of the top surface and a portion of the sidewall.

An interface of the Ag-based layer and the doped surface can have a reflectivity greater than ninety percent for light with a wavelength in a range of 450 to 650 nanometers (nm).

The passivation layer can have a refractive index greater than 1.7 for light with a wavelength in a range of 450 to 650 nanometers (nm).

The passivation layer can be configured to getter at least one of oxygen, or hydrogen.

The passivation layer can be configured to trap mobile charges.

In another general aspect a micro-light-emitting diode (microLED) includes a semiconductor structure having a doped surface; and a light-emitting region. The microLED also includes a metal-based layer electrically contacting at least a portion of the doped surface, and a passivation layer disposed on the semiconductor structure. A portion of the passivation layer is in physical contact with the metal-based layer. The passivation layer is a compound including a II-nitride material. The microLED has a lateral dimension of less than or equal to 10 micrometers (μm).

Implementations can include one or more of the following features or aspects, alone or in combination. For example, the metal-based layer can be an Ag-based layer. A first portion of the Ag-based layer can be disposed on the doped surface. A second portion of the Ag-based layer can be disposed on the passivation layer.

The semiconductor structure can include a III-Nitride material.

The II-Nitride material can include at least one of magnesium nitride, calcium nitride, or beryllium nitride.

The compound can further include a Group III element.

The passivation layer can include, by composition, at least ninety percent of the II-Nitride material.

The semiconductor structure can include a layer including gallium nitride (GaN), and a light-emitting layer including indium gallium nitride.

An interface of the metal-based layer and the doped surface can have a reflectivity greater than ninety percent for light with a wavelength in a range of 450 to 650 nm.

The passivation layer can have a refractive index higher than 1.7 for light with a wavelength in a range of 450 to 650 nm.

The passivation layer can be configured to getter at least one of oxygen, or hydrogen.

The passivation layer can be configured to trap mobile charges.

In another general aspect an LED includes a semiconductor structure having a doped surface and a light-emitting region, a silver-based (Ag-based) layer electrically contacting at least a portion of the doped surface; and a passivation layer formed on a surface of the semiconductor structure. A portion of the passivation layer is in physical contact with the Ag-based layer. The passivation layer includes a chemical element X with a formation enthalpy for an oxide XO of greater than 500 kilo-joules per mole.

Implementations can include one or more of the following features or aspects, alone or in combination. For example, the passivation layer can include a compound of X and nitrogen.

A first portion of the Ag-based layer can be disposed on the doped surface. A second portion of the Ag-based layer can be disposed on the passivation layer.

The LED can have a lateral dimension of less than or equal to 10 μm.

The semiconductor structure can include a III-Nitride material.

X can be a Group II element.

The passivation layer can include a Group III element.

The passivation layer can include, by composition, at least ten percent of X.

The semiconductor structure can include a layer including gallium nitride (GaN), and a light-emitting layer including indium gallium nitride (InGaN).

An interface of the Ag-based layer and the doped surface can have a reflectivity greater than ninety percent for light with a wavelength in a range of 450 to 650 nm.

The passivation layer has a refractive index greater than 1.7 for light with a wavelength in a range of 450 to 650 nanometers nm.

The passivation layer can be configured to getter at least one of oxygen, or hydrogen.

The passivation layer can be configured to trap mobile charges.

In another general aspect, a method for producing a light-emitting diode (LED) includes forming a silver-based (Ag-based) layer on a doped surface of a semiconductor structure including a light emitting region. The Ag-based layer electrically contacts the doped surface. The method also includes forming a dielectric layer on the semiconductor structure. The dielectric layer is proximate the Ag-based layer. After forming the Ag-based layer and the dielectric layer, the method includes performing a thermal processing operation on the semiconductor structure, where the dielectric layer is configured to maintain a reflectivity of the Ag-based layer of greater than or equal to 80% for light at a wavelength of 500 nm after the thermal processing operation.

Implementations can include one or more of the following features or aspects, alone or in combination. For example, the dielectric layer can include a group II-nitride material.

The dielectric layer can include a chemical element X with a formation enthalpy for an oxide XO of greater than 500 kilo-joules per mole.

The thermal processing operation can be performed, at least in part, at a temperature of greater than or equal to 3000 Celsius (C).

The thermal processing operation can be one of an annealing operation for the Ag-based layer, a semiconductor doping activation operation, a metal reflow operation, or a metal bonding operation.

Maintaining the reflectivity can include the dielectric layer gettering at least one of hydrogen or oxygen during the thermal processing operation.

The dielectric layer can trap mobile charges.

Forming the dielectric layer can include forming the dielectric layer such that at least a portion of the dielectric layer is in physical contact with the Ag-based layer.

A chemical species can be present during the thermal processing operation. The dielectric layer can getter the chemical species. The chemical species can be one of oxygen or hydrogen.

In another general aspect, for a light emitting diode (LED) having a semiconductor structure with a doped surface and a light-emitting region, a silver-based (Ag-based) layer electrically contacting at least a portion of the doped surface, a dielectric passivation layer including a II-Nitride material formed on a surface of the semiconductor structure with a portion of the dielectric passivation layer being in physical contact with the Ag-based layer, a method of operating includes operating the LED with an electrical power, such that a light emitting region of the LED emits light. The dielectric passivation layer is configured, during the operating, to facilitate stable operation of the LED.

Implementations can include one or more of the following features or aspects, alone or in combination. For example, facilitating stable operation of the LED can include the dielectric passivation layer trapping mobile charges.

Stable operation of the LED can be characterized by a substantially constant light output of the LED over time.

Stable operation of the LED can be characterized by an amount of hysteresis of a current-voltage characteristic of the LED being below a threshold value. The threshold value, at an operating current of the LED, can be 50 millivolts. The operating current can correspond to a current density of greater than 1 amp per centimeter-squared in the light-emitting region.

The LED can have a lateral dimension of less than 10 micrometers.

The Ag-based layer can have a reflectivity of greater than or equal to 90% for light emitted by the light-emitting region at a wavelength of 500 nanometers.

In another general aspect, a method for producing a light-emitting diode (LED) includes forming a semiconductor LED mesa, forming a protective layer on the semiconductor LED mesa, forming a metal contact on the semiconductor LED mesa, and performing a processing operation on the LED. The processing operation causes a release of a species, The protective layer is configured to reduce diffusion of the species towards the semiconductor LED mesa.

Implementations can include one or more of the following features or aspects, alone or in combination. For example, the species can be oxygen or hydrogen.

The semiconductor LED mesa can have a sidewall, and the protective layer can cover a portion of the sidewall.

The protective layer can getter the species.

The protective layer can include a chemical element X that reacts with the species to form one of an oxide XO, or a hydride XH.

The protective layer can act as a diffusion barrier for the species.

The protective layer can have a thickness of at least 5 nm.

The protective layer can trap mobile charges.

The metal contact can be an Ag-based contact.

The protective layer can be in direct contact with the Ag-based contact, and can cause the Ag-based contact to maintain a high reflectivity during the processing operation.

The protective layer can reduce diffusion of the species towards the Ag-based contact.

In another general aspect, a light-emitting diode (LED) includes a semiconductor mesa having an n-doped region; an active region; and a p-doped region terminated by a p-surface. The LED also includes a p-contact disposed on a portion of the p-surface. The p-contact includes an Ag-based layer electrically contacting the p-surface, and a metal stack that encapsulates the Ag-based layer. The metal stack includes at least one layer of a conductive compound including a metal and nitrogen.

Implementations can include one or more of the following features or aspects, alone or in combination. For example, the conductive compound can act as a diffusion barrier for hydrogen.

The metal can include one of titanium, magnesium, cobalt, tantalum, or tungsten.

The conductive compound can include one of titanium nitride, magnesium nitride, cobalt nitride, tantalum nitride, or tungsten nitride.

The conductive compound can have a resistivity less than 1e⁻³ ohm·cm.

The at least one layer of conductive compound can have a resistance less than 10⁵ ohms.

The metal stack can include a first metal disposed between the Ag-based layer and the conductive compound, and a second metal disposed the conductive compound opposite the Ag-based layer.

The Ag-based layer can be in direct contact with the p-surface.

A transparent oxide can be disposed between the Ag-based layer and the p-surface.

The LED can have a first hydrogen concentration in the Ag-based layer and a second hydrogen concentration on a side of the at least one layer of the conductive compound opposite the Ag-based layer. The second hydrogen concentration can be at least ten times the first hydrogen concentration.

In another general aspect, a light-emitting diode (LED) includes a semiconductor mesa having an n-doped region, a light-emitting region, a p-doped region terminated by a p-surface, and at least one sidewall. The LED also includes a p-contact formed on a portion of the p-surface. The p-contact includes at least one layer of a conductive compound including a first metal and nitrogen. The LED further includes a passivation layer formed on a portion of the at least one sidewall. The passivation layer includes at least one layer of an insulating compound including a second metal and nitrogen.

Implementations can include one or more of the following features or aspects, alone or in combination. For example, the conductive compound can act as a diffusion barrier for hydrogen.

The first metal can include one of titanium, magnesium, cobalt, tantalum, or tungsten.

The conductive compound can include one of titanium nitride, magnesium nitride, cobalt nitride, tantalum nitride, or tungsten nitride.

The conductive compound can have a resistivity less than 1e⁻³ ohm·cm.

The at least one layer of the conductive compound has a resistance less than 10⁵ ohms.

The LED can include a third metal disposed between the p-contact and the conductive compound, and a fourth metal disposed on the conductive compound opposite the p-contact.

The second metal can include one of magnesium, calcium, or beryllium.

The insulating compound can include one of magnesium nitride, calcium nitride, or beryllium nitride.

In another general aspect, a method for producing an LED includes forming a p-contact in direct contact with a p-surface of an LED semiconductor mesa, and forming a metal stack on the p-contact, where the metal stack has a conductive barrier layer. The method also includes performing a processing operation on the LED. The processing operation uses, or causes a release of hydrogen. The conductive barrier layer is configured to reduce diffusion of the hydrogen through the p-contact to the p-surface during the processing operation.

Implementations can include one or more of the following features or aspects, alone or in combination. For example, the p-contact can be Ag-based.

The conductive barrier layer can be configured such that a flow of the hydrogen to the p-surface during the processing operation is less than 10¹³ cm-2.

The conductive barrier layer can be configured such that an additional hydrogen concentration, as a result of diffusion hydrogen during the processing operation, proximate the p-surface after the processing operation is less than 10¹⁹ cm⁻³.

The processing operation can include depositing silicon oxide deposition using a TEOS precursor.

The processing operation can occur at a temperature above 300° C.

The p-contact can have a specific contact resistance that is less than 1e⁻⁴ ohm cm² after the processing operation.

### BRIEF DESCRIPTION OF DRAWINGS

FIG. 1 is a diagram illustrating an example light-emitting diode (LED) device.

FIG. 2 is a diagram illustrating a gettering function of an example passivation layer.

FIG. 3 is a graph illustrating experimental results demonstrating stability and/or optical performance improvements of a silver-based (Ag-based) contact in an example LED with a gettering passivation layer.

FIGS. 4A-4F are diagrams illustrating examples of Ag-based contacts.

FIG. 5A-5F are diagrams illustrating example LED devices including gettering passivation layers.

FIG. 6 is flowchart illustrating an example method for producing an electronic device, such as a microLED.

FIG. 7 is a graph illustrating experimental results demonstrating improved electrical stability of LEDs with gettering passivation layers.

FIG. 8 is a diagram illustrating an example LED with an Ag-based contact that is encapsulated by a barrier layer, where contact layers of the LED are planar.

FIG. 9 is a diagram illustrating an example LED with an Ag-based contact that is encapsulated by a barrier layer, where materials surrounding the Ag-based contact are non-planar and surround the Ag-based contact.

FIG. 10 is a diagram illustrating an example LED with an Ag-based contact encapsulated by a barrier layer and impurity-gettering passivation.

FIG. 11 is a graph illustrating experimental data demonstrating improved performance associated with use of a barrier layer.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated.

### DETAILED DESCRIPTION

This disclosure is directed to electronic devices, such as semiconductor devices, that include an electrically conductive and optically reflective contact. For instance, implementations described herein include light-emitting diodes (LEDs), such microLEDs, e.g., LEDs with lateral dimensions of 10 micrometers (μm) or less. In some implementations, a microLED includes, among other elements, a semiconductor structure (semiconductor member, semiconductor stack, etc.), an Ag-based contact, and a dielectric passivation layer (dielectric layer, protective layer, etc.). In some implementations, the semiconductor structure includes an n-doped region, a p-doped region and an active, light-emitting region (an active region, a light-emitting region, an active quantum-well (QW) region, etc.).

In some implementations, the electrically conductive and optically reflective contact can include a silver-based (Ag-based) contact that provides electrical contact to the p-doped region of the semiconductor structure, with a low contact resistance (electrical resistance) and a high optical reflectivity for light emitted by the active region. In some implementations, the passivation layer can serve one or more purposes. For instance, in some implementations, the passivation layer can reduce non-radiative recombinations (non-light emitting carrier recombinations) at surfaces of the LED. In some implementations, the passivation layer can trap mobile charges, thus facilitating stable electrical operation of the LED (e.g., without hysteresis, or with significantly reduces hysteresis below a threshold value). In some implementations, the passivation layer can getter oxygen (O) and/or hydrogen (H) (or other chemical species). For instance, gettering of oxygen can help prevent oxidation of the Ag-based contact (which can increase contact resistance and/or reduce reflectivity). Gettering of hydrogen can help prevent passivation of the p-doped region (which can increase contact resistance). In some implementations, the passivation layer (e.g., a gettering-passivation layer) can have low oxygen content or concentration, such as described herein.

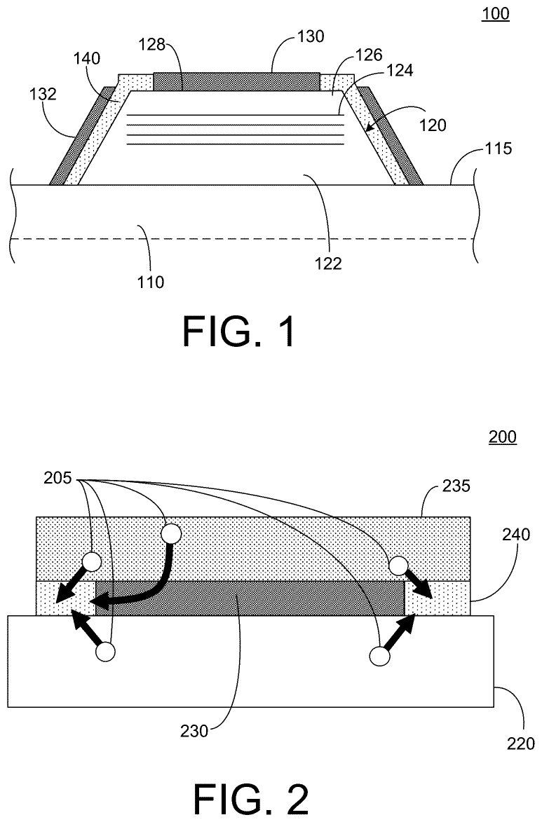

FIG. 1 is a diagram illustrating an example of a microLED 100 (e.g., a cross-sectional view of the microLED 100). As shown in FIG. 1, the microLED 100 includes a buffer layer 110 (e.g., a gallium nitride (GaN) buffer layer) having a growth interface surface 115, e.g., for epitaxial growth a microLED mesa 120. As shown in FIG. 1, the microLED mesa 120 is formed on the growth interface surface 115. In some implementations, formation of the microLED mesa 120 may be achieved by selective area epitaxial growth, planar epitaxial growth and etch-back, subsequent regrowth steps, and/or other processes. As shown in FIG. 1, the microLED mesa 120 of the microLED 100 includes at least one n-doped layer 122, an active region 124 (active QW region), and at least one p-doped layer 126. In this example, the microLED mesa 120 has sidewalls that are slanted or sloped. In some implementations, a microLED can have sidewalls that are vertical, and/or have other shapes. In some implementations, the microLED mesa 120 has a p-doped top surface 128 (e.g., as in the arrangement shown in FIG. 1).

As shown in FIG. 1, the microLED 100 includes an Ag-based contact 130. In this example, the Ag-based contact 130 is formed on a portion of the p-doped top surface 128. The microLED 100 also includes a passivation layer 140 that is disposed on a portion of the microLED mesa 120 proximate to the Ag-based contact 130 (e.g., adjacent to the Ag-based contact 130, in contact with the Ag-based contact 130, etc.). In some implementations, as in the microLED 100, the passivation layer 140 may be formed on at least a portion of the p-doped top surface 128 and/or on a least a portion of the sidewalls of the microLED mesa 120. In some implementations, such as those described herein, the passivation layer 140 can improve optical performance of the microLED 100, e.g., by gettering impurities during semiconductor processing, and/or improve electrical operation stability of the microLED 100, e.g., by passivating electrical traps. The microLED 100 also includes a reflector 132 that is disposed on a portion of the microLED 100. In this example, the reflector 132 is disposed on a portion of the passivation layer 140 on the sidewalls of the microLED mesa 120. The reflector 132, in the microLED 100, is electrically isolated from the Ag-based contact 130. In some implementations, a reflector, such as the reflector 132, can be connected (electrically and/or physically) to the Ag-based contact 130. The reflector 132 may be a high-reflectivity layer, such as an Ag-based mirror.

In some implementations, the passivation layer 140 can have one or more of the following characteristics or attributes. In some implementations, the passivation layer 140 may be a dielectric layer that includes a material composition of nitrogen (N) and an element X, where X is an element with a high enthalpy for the formation of an oxide, and/or a low solubility with other elements. For instance, X can have an enthalpy of greater than 500 kilo-joules per mole for the formation of an oxide XO. In some implementations, the passivation layer 140 may be substantially a nitride-based dielectric (such as SiN). In some implementations, the passivation layer 140 may be a dielectric layer combining a Group II element and nitrogen (N), e.g., a II-Nitride material. In some implementations, the Group II element may be one of magnesium (M), calcium (Ca), or beryllium (Be). In some implementations, the passivation layer 140 can be, by composition, at least ninety percent (90%) a II-nitride material. In some implementations, X can, instead, form a hydride XH.

In some implementations, the passivation layer 140 may be a compound containing a Group II element, nitrogen, and at least one additional element. Additional elements can include Group III elements, such as boron (B), aluminum (Al), gallium (Ga), or indium (In). In some implementations, the passivation layer 140 may be a dielectric layer including or containing magnesium or magnesium nitride, for instance Mg₂N₃ (though other stoichiometries, or departures from this exact stoichiometry, are possible), such as materials including or containing Ca or CaN, for instance, or materials including or containing Be or BN, for instance. In some implementations, the passivation layer 140 may have a very low concentration of oxygen (e.g., less than 1e15 cm⁻³, less than 1e14 cm⁻³, less than 1e13 cm⁻³, less than 1e12 cm⁻³, less than 1e11 cm⁻³, or less than 1e10 cm⁻³). In some implementations, the passivation layer 140 may include carbon (C).

In some implementations, the passivation layer 140 can include a dielectric that includes, or contains at least two of Mg, Ca, Be, N, C, or O. In some implementations, material of the passivation layer 140 may include, or contain a macroscopic quantity of some elements. For instance, in some implementations, at least 1% (at least 5%, at least 10%, or at least 20%) of the atomic composition can be Mg, Ca, or Be, and at least 1% (at least 5%, at least 10%, at least 20%) of the atomic composition can be at least one of N, C, or O. In some implementations, at least 10% of the atomic composition of the passivation layer 140 is Mg, Ca, or Be, and at least 10% is N.

In some examples, material (or a portion thereof) of the passivation layer 140 is substantially made of (e.g., only made of) a II-Nitride material. In some implementations, the atomic composition of any other element is less than 1% (less than 0.1%, less than 0.01%, less than 0.001%, or less than 0,0001%). In some examples, a density of other elements (other than a II-Nitride material), as measured by SIMS, is less than 1e20 cm⁻³ (less than 1e19 cm⁻³, less than 1e18 cm⁻³, less than 1e17 cm⁻³, less than 1e16 cm⁻³, or less than 1e15 cm⁻³).

The passivation layer 140 may have at least one of the following properties. In some examples, the passivation layer 140 acts as an oxygen-gettering layer and/or a hydrogen-gettering layer. In some implementations, oxygen and/or hydrogen may originate from various sources in the structure of the microLED 100, and/or from processing operations used to produce the microLED 100. Oxygen and/or hydrogen may move (e.g., migrate, diffuse, etc.) across or through the structure of the microLED 100 (e.g., by diffusion, migration, etc.). In some implementations, migration of oxygen and/or hydrogen towards, or to a reflective layer (such as an Ag-based layer) may be detrimental to its reflectivity and/or its contact resistance. Accordingly, in some implementations, the passivation layer 140 can getter oxygen and/or hydrogen, thus reducing their diffusion towards the Ag-based contact 130. In some implementations, this may result in a metal layer with a high reflectivity, and may also improve operating stability and performance of an associated device, e.g., the microLED 100. In some implementations, a metal layer (contact layer) used in a device, e.g., the microLED 100, can be substantially Ag-based, e.g., the Ag-based contact 130. In some examples, such a metal layer has a reflectivity great than 90% (greater than 95%, of greater than 97%). The reflectivity may be at a wavelength in the visible range 400-700 nm, e.g. at 500 nm, in a range of 450-650 nm, etc. In some examples, the metal layer can be a reflective metal stack with a reflectivity of at least 80% (at least 85%, at least 90%, or at least 95%).

In some implementations, the passivation layer 140 can function (e.g., act) as both an impurity-gettering layer and a charge trap. As used herein, an impurity is an element (e.g., oxygen and/or hydrogen) that can propagate (diffuse, migrate, etc.) through a structure and impair (e.g., spoil, degrade, etc.) a reflectivity of a metallic layer, such as the Ag-based contact 130, and/or increase an electrical resistance of a contact formed using the metallic layer (Ag-based contact 130).

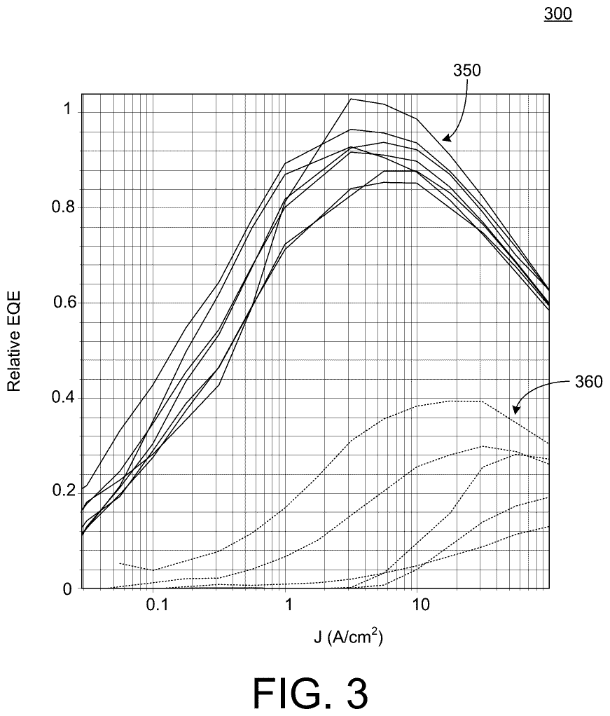

FIG. 2 is a diagram illustrating an impurity-gettering function of a passivation layer 240 in an electronic device 200, such as for impurities 205, where the electronic device 200 can be a microLED, or other device. As with the view of the microLED 100 in FIG. 1, the view of the electronic device 200 in FIG. 2 is a cross-sectional view. In this example, the electronic device 200 includes a semiconductor structure 220 (e.g., a semiconductor member, a semiconductor stack, etc., which may be doped, e.g., n-doped or p-doped), an Ag-based contact 230, a metal stack 235, and the passivation layer 240, which can be a passivation layer as described herein. As shown in FIG. 2, the metal stack 235 can be disposed on the Ag-based contact 230 and the passivation layer 240, where the passivation layer 240 is proximate (e.g., adjacent to, and/or in contact with) the Ag-based contact 230.

In some implementations, the impurities 205 may originate from the semiconductor structure 220, from metals in the metal stack 235, and/or from other layers in the electronic device 200. In some implementations, the impurities 205 may also come from an ambient environment during a processing operation (e.g., from a liquid or gas used during processing). In some implementations, the impurities 205 can propagate through the electronic device 200. Such migration may occur due to, for example, diffusion. In some implementations, propagation of the impurities 205 may be facilitated by attributes of a processing operation and/or operation of the electronic device 200, such as a high-temperature processing operation (e.g., above 3000 Celsius (C)), an applied bias, and so forth. In some implementations, the impurities 205 may be detrimental to a reflectivity of the Ag-based contact 230, and/or can passivate the semiconductor structure 220 at an interface with the Ag-based contact 230, resulting in an increase in electrical resistance of an associated contact to the semiconductor structure 220.

In some implementations, such as in the example of FIG. 2, the passivation layer 240 getters the impurities, causing their capture and/or preventing them from impairing (e.g., spoiling) the reflectivity of the Ag-based contact 230, and/or from increasing associated contact resistance. In some implementations, the impurities 205, once gettered, may be stable in the passivation layer 240. For instance, the impurities can remain within the passivation layer 240 during further processing and/or use of the electronic device 200 (e.g., high temperature operations, device operation, etc.). In some implementations, this stability may be provided, e.g., by formation of chemical bonds between the impurities 205 and the passivation layer 240, and/or by the impurities 205 being trapped in the passivation layer 240.

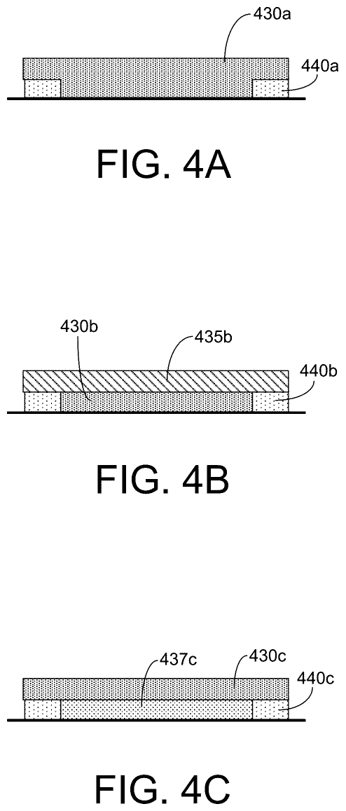

FIG. 3 is a graph 300 illustrating experimental results demonstrating that a gettering-passivation layer (e.g., the passivation layer 140, the passivation layer 240, etc.) can facilitate improved stability and/or optical performance of an Ag-based contact. In the graph 300, the traces 350 illustrate experimental results for a microLED with a gettering-passivation layer, while the traces 360 illustrate experimental results for a prior device that does not include a gettering-passivation layer. The microLEDs, in both instances in the graph 300, include an Ag-based contact, and are on the order of 2 μm (in lateral diameter). The experimental results illustrated in FIG. 3 where collected by operating respective microLEDs with an electrical power, such that a light emitting region of the LED emits light. For the microLED devices corresponding with the traces 350, their dielectric passivation layer, during their operation, facilitates stable operation of the LED, such as described herein.

In the graph 300, relative (normalized) external quantum efficiency (EQE) for the devices corresponding with the traces 350 and the traces 360 is shown. As can be seen in FIG. 3, from the traces 360 as compared with the traces 350, the microLEDs devices without a gettering-passivation layer (traces 360) have a severely suppressed EQE, caused by degradation of the Ag-based contact from impurities during the device process, and/or by additional diffusion of impurities during operation. The microLEDs including a gettering-passivation layer (traces 350), in contrast, have a relatively high EQE, facilitated by a high-reflectivity Ag-based contact, as well as low associated contact resistance, e.g., as a result of the gettering action of the passivation layer. In some implementations, although the experimental results of FIG. 3 are discussed with respect to microLEDs with Ag-based contacts, these stability and optical performance improvements may also occur for metal contact (e.g., to p-doped layers of an LED mesa) that do not include or contain Ag, such as for contacts that are platinum (Pt) based or Ni based, and/or include other metals or materials.

As noted above, in some implementations, a gettering-passivation layer can include or contains a chemical element X, which has a high enthalpy (in absolute value) for formation of an oxide layer (e.g., in the form of XO). In some implementations, the enthalpy may be at least 500 kJ/mol. By way of example, enthalpy of formation (denoted as DHr, and having a negative value) of some oxides are shown in Table 1 below.

TABLE 1

| | −DHr (kJ/mol) |
|---|---|
| Mg | 602 |
| Al | 556 |
| Co | 238 |
| Cr | 192 |
| Cu | 155 |
| Nb | 381 |
| Ta | 410 |
| Ti | 473 |
| W | 293 |
| B | 427 |
| Si | 452 |
| Ni | 74 |

In some implementations, a passivation layer, such as the passivation layers described herein, in addition to gettering-impurities, can also reduce non-radiative recombinations. For instance, when formed over a surface of a semiconductor structure of an LED mesa (e.g., a microLED mesa), the example passivation layers may passivate dangling bonds. In some implementations, the surface may be characterized by a recombination velocity less than 1e5 cm/s (less than less than 1e4 cm/s, less than 1e3 cm/s, less than 1e2 cm/s, or less than 1e1 cm/s). In some implementations, a passivation layer, such as those described herein, may reduce recombination velocities by at least 10 times, when compared to prior implementations.

Passivation layers, such as those described herein, and corresponding electronic devices (e.g., semiconductor devices, LEDs, microLEDs, etc.) can have one or more of the following attributes. For instance, in some examples, a passivation layer has a refractive index in a range of 2.3-2.7. In some examples, the passivation layer has a refractive index within +/−0.1 (+/−0.2, +/−0.3, or +/−0.5) of the index of GaN. In some examples, a passivation layer has a refractive index greater than 1.7 (greater than 1.8, greater than 1.9, or greater than 2).

A passivation layer can be a stack of multiple materials. In some implementations, such a stack may include a combination of materials such as those described herein, as well as other materials, such as silicon oxides (SiOₓ), silicon nitrides (SiNₓ), aluminum oxides (AlOₓ), and/or other materials.

A device can have a passivation layer (a first layer) which is Group II-rich (for instance, including or containing at least 10% atomic composition of Mg, Ca, Be, or other Group II element), and a second layer overlying the first layer where the second layer maintains the stability (e.g., chemical and/or mechanical stability) of the Group II-rich layer. In some implementations, the second layer may fully encapsulate the first layer. In some implementations, the second layer may preclude contact between the first layer and air, other gasses (e.g., gasses including or containing O, C), and/or fluids, such as during a processing operation, or during operation of the device).

In some implementations, a metallic contact can be Ag-based, as shown in FIGS. 1 and 2 (e.g., the Ag-based contact 130, or the Ag-based contact 230, respectively). In some implementations, this can include contacts with various stack configurations where silver is a main element, e.g., a bulk stack with at least 99% (at least 99.9%, or at least 99.99%) Ag.

In some implementations, a metallic contact can include, or can be a multilayer stack, where bulk layers of Ag are alternated with other metals, such as nickel (Ni), platinum (Pt), aluminum (Al), titanium (Ti), palladium (Pd), etc.), and/or transparent oxides (e.g., indium-tin oxide (ITO), zinc oxide (ZnO), etc.). In some implementations, a metallic contact can include, or can be a stack with a thin layer (e.g., less than 5 nm, less than 1 nm, or less than 0.5 nm) of a metal at an interface with a semiconductor structure, where the thin layer is covered by a bulk Ag layer, or Ag-based layer.

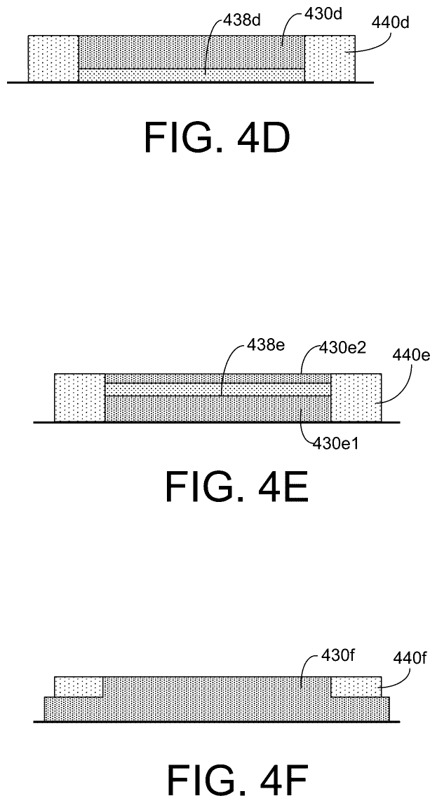

FIGS. 4A-4F are diagrams (e.g., cross-sectional views) illustrating examples arrangements of Ag-based contacts. As used herein, an Ag-based contact is a contact where silver substantially contributes to a high reflectivity of the contact. While not specifically shown in FIGS. 4A-4F, the illustrated example contacts can be disposed on (e.g., form an ohmic-contact interface) with an underlying semiconductor structure, such as with an LED mesa of a microLED.

FIG. 4A illustrates a pure Ag contact 430a, with a passivation material 440a in direct contact with the pure Ag contact 430a. FIG. 4B illustrates an Ag-based contact 430b covered by a metal stack 435b. As shown in FIG. 4B, a passivation layer 440b underlies at least one portion of the metal stack 435b, and is in contact with the Ag-based contact 430b. In this example, the metal stack 435b may improve adhesion (e.g. such that a layer in the metal stack 435b is in direct contact with the pure Ag contact 430a and has good adhesion to the pure Ag contact 430a), process stability, contact resistance, and/or mechanical resistance. FIG. 4C illustrates an ITO layer 437c, which can be in contact with underlying p-type GaN of an LED mesa (not shown), where the ITO layer 437c is covered by an Ag-based layer 430c. As shown in FIG. 4C, a passivation layer 440c underlies at least one portion of the Ag-based layer 430c, and is in contact with the ITO layer 437c (and the ag-based layer 430c). FIG. 4D illustrates a thin Ni layer 438d that is covered by an Ag-based layer 430d, with a passivation layer 440d in contact with the thin Ni layer 438d and the Ag-based layer 430d. In some implementations, the Ni layer 438d may have a thickness that is less than 10 nanometers (nm), less than 5 nm, less than 2 nm, less than 1 nm, less than 0.5 nm, or less than 0.1 nm In some implementations, the Ni layer may be continuous, e.g., formed of Ni islands in the case of a very thin layer). In some implementations, other metals (such as Pt) may also be used in place of the thin Ni layer 438d. FIG. 4E illustrates a thin Ni layer 438e embedded in an Ag matrix, e.g. between a first Ag layer 430e1 and a second Ag layer 430e2. A passivation layer 440e is in contact with the thin Ni layer 438e, the first Ag layer 430e1, and the second Ag layer 430e2. In some implementations, the thin Ni layer 438e may be discontinuous, and may diffuse into the Ag layer 438e1 and/or into the Ag layer 438e2 (e.g., during a process operation, during device operation, etc.). FIG. 4F illustrates an alternative of the example of FIG. 4A. In the example of FIG. 4F, a passivation layer 440f is disposed on top of an Ag layer 430f (rather than below the pure Ag contact 430a in FIG. 4A). In some implementations, the Ag layer 430f, can include a first Ag contact layer and, above that, a second Ag contact layer disposed within a recess (opening) defined in the passivation layer 440f.

In some implementations, variations and combinations of elements other than those specifically shown in FIGS. 4A-4F are also possible. In some implementations, Ag layers (e.g., Ag-based layers) may have a thickness of at least 50 nm (at least 100 nm, at least 150 nm, or at least 200 nm).

In some implementations, a metal/semiconductor interface (e.g., an interface between a metal contact and a semiconductor structure) may be characterized by a high reflectivity (e.g., a high reflectivity level, at an emission wavelength of an associated LED). For instance, in some implementations, the reflectivity may be above a target value (e.g., 80%, 90%, 95%, or 97%). In some implementations, using the approaches described herein, the reflectivity may be maintained at a relatively high level over time, e.g., as the corresponding device is operated.

In some implementations, a device that is operated for an extended time (e.g., 1000 hours or more) at an operating current density (e.g., at least 1 amp per centimeter-squared (A/cm²)) can have a reflectivity that remains substantially constant. In some implementations, this relatively stable reflectivity may be facilitated by configuration of (material content of) a passivation layer (e.g., where the passivation layer getters impurities that could otherwise reduce, or degrade reflectivity).

In some implementations, a metal/semiconductor interface may be characterized by parameters of an electrical contact. For instance, in some implementations, an electrical contact may have a low (or zero) Schottky barrier. In some implementations, an electrical contact may have a contact resistivity less than 5e-1 Ohms/cm² (Ω/cm²), less than 1E-1 Ω/cm², less than 5E-2 Ω/cm², less than 1E-2 Ω/cm², less than 5E-3 Ω/cm², or less than 1E-3 Ω/cm2.

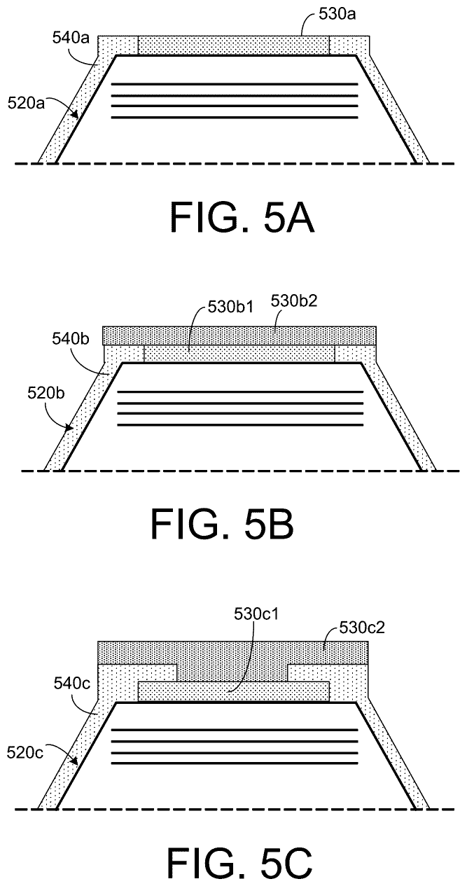

FIGS. 5A-5F are diagrams (e.g., cross-sectional views) illustrating various example arrangements of microLED devices implemented using the approaches described herein, e.g., including gettering-passivation layers. While not specifically shown in FIGS. 5A-5F, the illustrated devices, e.g., microLED mesas, can be disposed (formed, etc.) on a growth interface of an underlying semiconductor material, e.g., a GaN buffer layer.

In the example of FIG. 5A, a passivation layer 540a (e.g., a gettering-passivation layer) is formed on at least a portion of a top p-surface and sidewalls of a microLED mesa 520a. In some implementations, the sidewalls may be, for example, p-doped, n-doped, or include a p-n junction. In some implementations, an Ag-based p-contact 530a is formed on a portion of the top p-surface of the microLED mesa 520a, and in contact with the passivation layer 540a.

In the example of FIG. 5B, a p-contact to a microLED mesa 520b includes a stack of metals, e.g., including a p-contact 530b1 and a p-contact 530b2, either of which may be Ag-based. In some implementations, the other p-contact layer (other than an Ag-based contact layer) may include one or more other metals, such as Al, Pt, gold (Au), Ni, Ti, Pd), and/or transparent conductive oxides (such as ITO, ZnO, etc.). In some implementations, the p-contact 530b1 is, at least in part, formed in (disposed in) an opening in a passivation layer 540b (e.g., a gettering-passivation layer).

In the example of FIG. 5C, a p-contact layer 530c1 (e.g., an Ag-based layer) is formed as a p-layer contact to a microLED mesa 520c. The p-contact layer 530c1 is covered by a passivation layer 540c (e.g., a gettering passivation layer) and an opening is formed in the passivation layer 540c. At least one additional metal layer (e.g., a metal layer 530c2) can be formed, where at least a portion of the metal layer 530c2 is disposed in the opening in the passivation layer 540c, and in contact with the p-contact layer 530c1. The P-contact layer 530c1 and the metal layer 530c2 can include Ag and/or other metals such as Ti, Pt, Ni, gold (Au), chromium (Cr), tungsten (W), Al.

In the example of FIG. 5D, a passivation layer 540d (e.g., a gettering-passivation layer) is formed on a portion of a top surface of a microLED mesa 520d, but does not cover any portion of sidewalls of the microLED mesa 520d. In some implementations, the sidewalls of the microLED mesa 520d can be covered by a second passivation layer (either made of the same material as the passivation layer 540d, or a different dielectric material). As with the example of FIG. 5B, a p-contact to a microLED mesa 520d includes a stack of metals, e.g., including a p-contact 530d1 and a metal layer 530d2, either of which may be Ag-based. In some implementations, the other p-contact layer (other than an Ag-based contact layer) may include one or more other metals, such as Al, Pt, Au, Ni, Ti, Pd), and/or transparent conductive oxides (such as ITO, ZnO, etc.). In some implementations, the p-contact 530d1 is, at least in part, formed in (disposed in) an opening in the passivation layer 540d.

FIG. 5E illustrates a microLED device that is similar to the example of FIG. 5C, where sidewalls of a microLED mesa 520e are vertical, rather than sloped or slanted, with no semiconductor material laterally surrounding an associated active region (e.g., between the active region and the sidewalls). As with the example of FIG. 5C, in the example of FIG. 5E, a p-contact layer 530e1 (e.g., an Ag-based layer) is formed as a p-layer contact to the microLED mesa 520e. The p-contact layer 530e1 is covered by a passivation layer 540e (e.g., a gettering passivation layer) and an opening is formed in the passivation layer 540e. At least one additional metal layer (e.g., a metal layer 530e2) can be formed, where at least a portion of the metal layer 530e2 is disposed in the opening in the passivation layer 540c, and in contact with the p-contact layer 530e1.

In the example of FIG. 5F, a p-contact 530f is formed, in part, on sidewalls and a top surface of a microLED mesa 520f. In the example, the microLED mesa 520f has p-layers (e.g. p-GaN) on its sidewalls, surrounding a corresponding active region of the microLED mesa 520f. These p-layers may be obtained by selective area growth from a patterned opening (with the growth progressing laterally) or from a regrowth step. In some implementations, this may be beneficial if the sidewalls have p-doped semiconductor material (e.g., either from selective growth on non-vertical plane(s), and/or from a growth step), which can promote lateral carrier injection into the active region. In this example, a passivation layer 540f (e.g., a gettering-passivation layer) may be in proximity to, or in physical contact with Ag-containing regions of the p-contact 530f. The example structure of FIG. 5F also includes a base dielectric layer 570 that is disposed around a base of the microLED mesa 520f. The base dielectric layer 570 may, e.g., correspond to a growth mask (or selective area growth mask), which is used for growing the microLED mesa 520f.

In example implementations, sidewalls of a microLED mesa can have a variety of geometries. For instance, sidewalls can be vertical, non-vertical, slanted, sloped, curved, and so forth. Quantum wells of a corresponding active region may or may not extend to the sidewalls. In some implementations, there may be p-type material (e.g. p-GaN, p-AlGaN) on the sidewalls surrounding the active region.

In some implementations, passivation material (gettering-passivation material) is in direct contact with an Ag-based material. In some examples, it is separated from an Ag-based material by a distance less than 100 nm (less than 10 nm, or less than 1 nm).

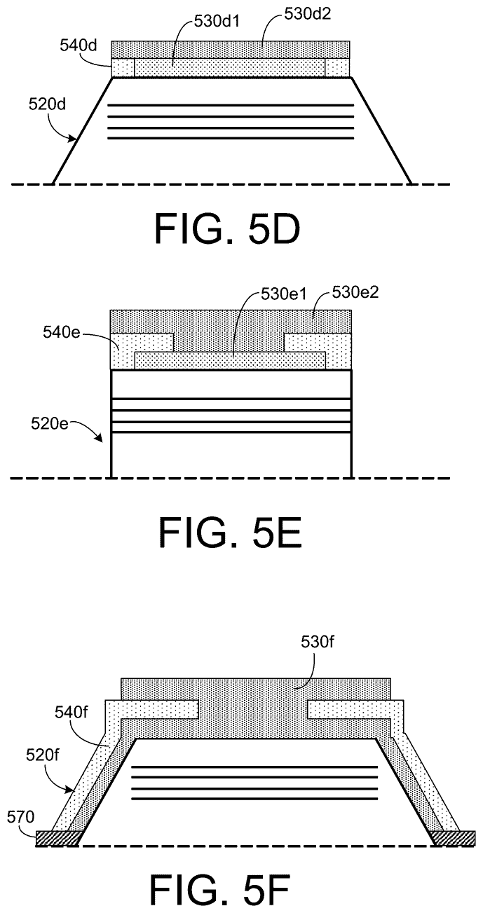

FIG. 6 is a flowchart illustrating an example method 600 for producing an electronic device, such as example implementations of microLEDs described herein. Depending on the particular implementation, the operations of the method 600 can be performed in a different order, additional operations can be performed, and/or operations included in FIG. 6 can be omitted. The method 600 is, accordingly, given by way of example and for purposes of illustration.

As shown in FIG. 6, the method 600 includes, at block 610, forming a semiconductor structure. In some implementations, the semiconductor structure can include an n-doped region, an active region and a p-doped region that are formed on a buffer layer (e.g., a semiconductor substrate or template). At block 620, the method 600 includes forming a microLED mesa from the semiconductor structure of block 610. In some implementations, the microLED mesa can be formed using a combination of dry and wet etching. In some implementations, the microLED mesa has a top surface and sidewalls. In some implementations, the top surface is doped (e.g., p-doped). In some implementations, the device has a lateral dimension (width) of less than 50 um (less than 10 um, less than 5 um, less than 2 um, or less than 1 um).

At block 630, a passivation layer (e.g., a gettering-passivation layer) is formed over at least a portion of the microLED mesa. In some implementations, this may include a portion of the sidewalls and/or a portion of the top surface. At block 640, a metallic contact layer (e.g., an Ag-based contact layer) is formed over a portion of the microLED mesa. In some implementations, this may include a portion of the sidewalls and/or a portion of the top surface. In some implementations, the metallic contact layer can be formed, at least in part, in an opening defined in the passivation layer. In some implementations, the passivation layer can be in close proximity to the metallic contact layer (e.g., in direct physical contact).

At block 650, the method includes performing a thermal processing operation. For instance, the operation at block 650 can include at least one of an annealing operation for the Ag-based layer, a semiconductor doping activation operation, a metal reflow operation, or a metal bonding operation. In some implementations, during the thermal processing operation of block 650, the passivation layer formed at block 630 may have an impurity-gettering effect, capturing impurities that diffuse, and/or precluding those elements from reacting with the metallic contact layer formed at block 640. For instance, the passivation layer can getter oxygen and/or hydrogen, precluding oxygen from reacting with a silver-based metallic contact layer and/or precluding hydrogen from passivating a contact surface of the microLED at an interface with the metallic contact layer.

In some implementations, the semiconductor structure may be formed by epitaxial growth techniques including metal-organic chemical-vapor deposition (MOCVD), molecular-beam epitaxy (MBE), etc. In some implementations, the passivation layer may be formed by techniques including sputtering, e-beam deposition, atomic layer deposition, CVD, plasma-enhanced CVD (PECVD), and high density plasma (HDP) deposition. In some implementations, co-deposition may be used, using a combination of two more of the foregoing techniques.

In some implementations, the metallic contact layer may be formed by techniques including sputtering, e-beam, plating (e.g., electro-chemical plating (ECP)) deposition, etc.

In some implementations, a device produced by the method 600 can be operated with an electrical power. In some implementations, the electrical power may have a current density of at least 0.1 A/cm² (at least 1 A/cm², at least 10 A/cm², or at least 100 A/cm²). In some implementations, such a device may be characterized by stable operation (e.g., optical and/or electrical operation). In some implementations, the stable operation may be facilitated by the presence of a gettering-passivation layer, such as those described herein. Stable operation can be contrasted with a device showing hysteresis and/or optical instability over time. Stable operation can be characterized by a stable light-current-voltage characteristic of an LED. For instance, hysteresis less than or equal to 50 millivolts (mV) can demonstrate stable operation.

In some examples, the passivation layer can getter charged defects. In some implementations, this gettering of charged defects can preclude those charged defects from causing unstable operation of an associated device. In some implementations, the charged defects may be one or more of a charged atom, a charged complex, a native semiconductor defect (such as a vacancy), and so forth. In some implementations, such as described herein, a p-contact cab have a specific contact resistance that is less than 1e-2 ohm cm² (less than 1E-3 Ohm cm2, or less than 1e-4 Ohm cm2) after the processing operation of block 650 of the method 600.

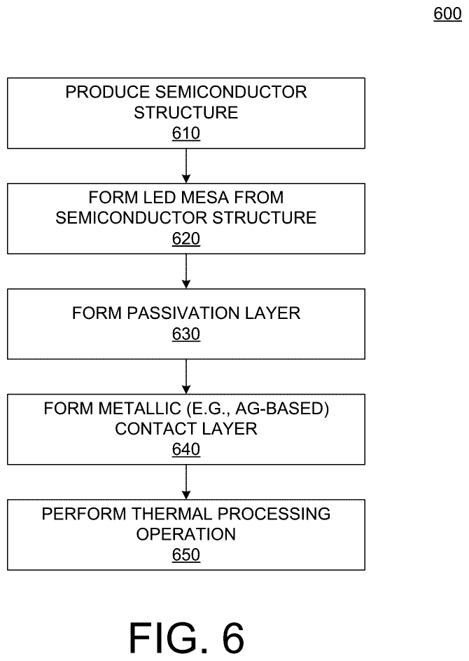

FIG. 7 is a graph 700 illustrating experimental results demonstrating that a gettering-passivation layer can improve electrical stability of an LED, where the traces 750 illustrate experimental results for microLEDs with a gettering passivation layer, and the traces 760 illustrate experimental results for microLEDs without a gettering passivation layer. The experimental results of FIG. 7 are for microLED devices on the order of 2 μm (in diameter) with metallic contact layers (e.g., Ag-based p-contacts). The experimental results illustrated in FIG. 7 where collected by operating respective microLEDs with an electrical power, such that a light emitting region of the microLED emits light. For the microLED devices corresponding with the traces 750, their dielectric passivation layer, during their operation, facilitates stable operation of the LED, such as described herein.

In FIG. 7, each set of traces (the traces 750 and the traces 760) illustrates respective relationships between measured voltage and current density for the corresponding LEDs, with a sweep up (with increasing voltage) being followed by a sweep down (with decreasing voltage). In the example of FIG. 7, dashed lines show respective sweeps up, while solid lines show respective sweeps down. In this example, the devices without a gettering-passivation layer (traces 760) have unstable J-V characteristics, where sweep up voltage and sweep down voltage at a given current varies by as much as 1 V (e.g., the LEDs operate with hysteresis). Further in this example, the devices including a gettering passivation layer (traces 750), in contrast, have a stable J-V characteristic; the sweep up and sweep down overlap in FIG. 7, showing no, or negligible hysteresis. In some implementations, the getting-passivation layer facilitates this stable J-V characteristic by passivating electrical traps.

In some instances, an unstable (or transient) J-V curve of a prior device implementation (e.g., without a gettering-passivation layer) may become more stable after operation, at least for a limited period of time, e.g., a burn-in step. In contrast, devices produced using the approaches described herein can operate with a stable J-V curve without a burn-in step, e.g., such may be stable upon first operation, and remain stable over extended periods of time during a use lifetime.

In some implementations, stability may be characterized by a variation in voltage less than a predetermined value (e.g., 1 V, 0.1 V, 0.05 V, 0.02 V) at a predetermined current or current density (e.g., 0.1 A/cm², 1 A/cm², 10 A/cm²). In some implementations, variation may occur between a sweep up (increasing voltages) and a following sweep down (decreasing voltages), and a gettering-passivation layer may reduce or remove this variation. In some implementations, stability may be observed as a steady current that is maintained for a period of time (e.g., at least 1 microsecond (μs), 1 millisecond (ms), 1 second (s), 1 minute (min), 1 hour (hr)). In some implementations, stability may be observed by two measurements at a same current that are performed within a period of time (e.g., within 1 μs, 1 ms, is, 1 min, 1 hr). In some implementations, stability may last for at least 1 day (or 1 month, or 1 year). In some implementations, a device (e.g., a microLED) driven at a predetermined current, for at least is, at least twice in one day can have a voltage that is stable within less than 0.1 V when driven at the predetermined current.

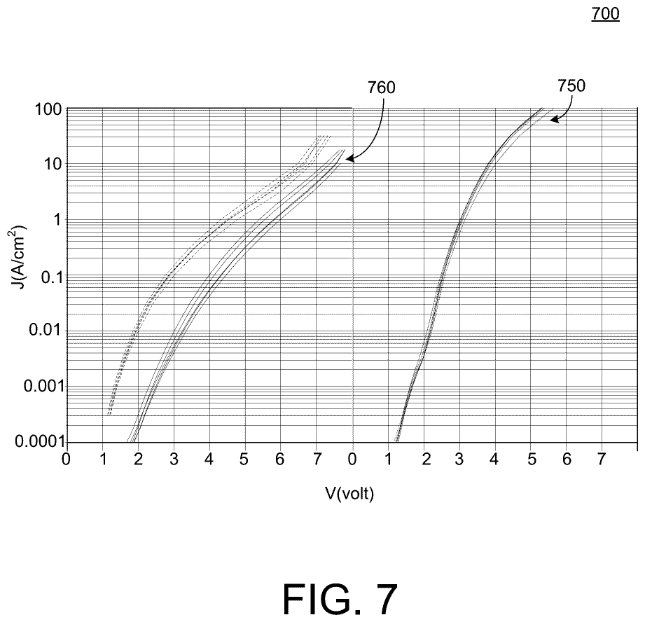

In some implementations, a barrier layer can be included in the contact metal stack, where the barrier layer can, e.g., alone or in combination with a gettering-passivation layer as described herein, improve the stability of a contact. As noted above, an interface (electrical contact interface) between contact metal (e.g., an Ag-based contact metal) and an underlying semiconductor material (e.g., a p-type GaN layer of a microLED) may be sensitive to the presence of hydrogen. For instance, diffusion of hydrogen during a process step may passivate the semiconductor material and, as a result, degrade, or increase an associated contact resistance. Further, metal contact layers and/or reflector layers can be sensitive to the presence of oxygen, which can oxidize the metal layers and degrade, or reduce their optical properties, e.g., their reflectivity. In the example implementations illustrated in FIGS. 8, 9 and 10, a barrier layer is included in metal stack, e.g., a contact metal stack, where the barrier layer prevents, or slows (inhibits, reduces, etc.) movement of hydrogen and/or oxygen towards an associated contact interface and/or a reflective metal layer. Such a barrier layer can include a conductive compound. For instance, a barrier layer can have a resistivity that is less than 1e⁻³ ohm·cm. In some implementations, a layer of such a conductive compound (barrier layer) can have resistance that his less than 10⁵ ohms.

In the following discussion, example metallic structures including respective barrier layers are described with respect to FIGS. 8 to 10. Such contact structures can be included, e.g., in a microLED, or other semiconductor (electronic) devices. Subsequent to the discussion of the example structures of FIGS. 8 to 10, example implementation details for those structures are described. Of course, the specific details of a given device will depend on the particular implementation.

FIG. 8 is a diagram that illustrates a contact metal stack 800 (e.g., a cross-sectional view of the contact metal stack 800) with planar layers. In this example, the contact metal stack 800 is formed on a surface 828 of a p-type layer (e.g., p-type GaN) of a microLED mesa. The contact metal stack 800 includes an Ag-based contact 830 that is disposed on (e.g., directly on) the surface 828. The contact metal stack 800 further includes a metal layer 835a (e.g., metal_1 layer) that is disposed on the Ag-based contact 830, a barrier layer 870 that is disposed on the metal layer 835a, and a metal layer 835b (e.g., metal_2 layer) that is disposed on the barrier layer 870. The contact metal stack 800, in this example, also includes a passivation layer 840 that is disposed adjacent to, and in contact with the metal layer stack including the Ag-based contact 830, the metal layer 835a, the barrier layer 870, and the metal layer 835b. Depending on the implementation, the passivation layer 840 can be a gettering passivation layer, such as those described herein, and can provide a gettering function for impurities, such as described with respect to, at least, FIG. 2. In some implementations, the passivation layer 840 may be a passivation layer that does not provide a gettering function.

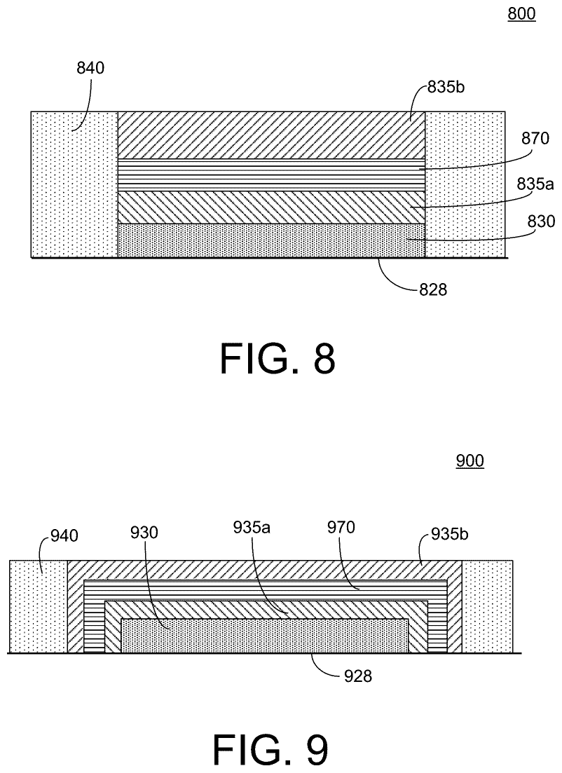

FIG. 9 is a diagram that illustrates a contact metal stack 900 (e.g., a cross-sectional view of the contact metal stack 900) that includes both planar and non-planar layers. In this example, the contact metal stack 900 is formed on a surface 928 of a p-type layer (e.g., p-type GaN) of a microLED mesa. The contact metal stack 900 includes an Ag-based contact 930 (e.g., a planar contact layer) that is disposed on (e.g., directly on) the surface 928. The contact metal stack 900 further includes a metal layer 935a (e.g., a non-planar metal_1 layer) that is disposed on, and encapsulates (at least partially surrounds) the Ag-based contact 930. The contact metal stack 900 further includes a barrier layer 970 (e.g., a non-planar barrier layer) that is disposed on, and encapsulates (at least partially surrounds) the metal layer 935a. The contact metal stack 900 further includes a metal layer 935b (e.g., a non-planer metal_2 layer) that is disposed on, and encapsulates (at least partially surrounds) the barrier layer 970. The contact metal stack 900, in this example, also includes a passivation layer 940 that is disposed adjacent to, and in contact with the metal layer 935b of the metal layer stack including the Ag-based contact 930, the metal layer 935a, the barrier layer 970, and the metal layer 935b. Depending on the implementation, the passivation layer 940 can be a gettering passivation layer, such as those described herein, and can provide a gettering function for impurities, such as described with respect to, at least, FIG. 2. In some implementations, the passivation layer 940 may be a passivation layer that does not provide a gettering function.

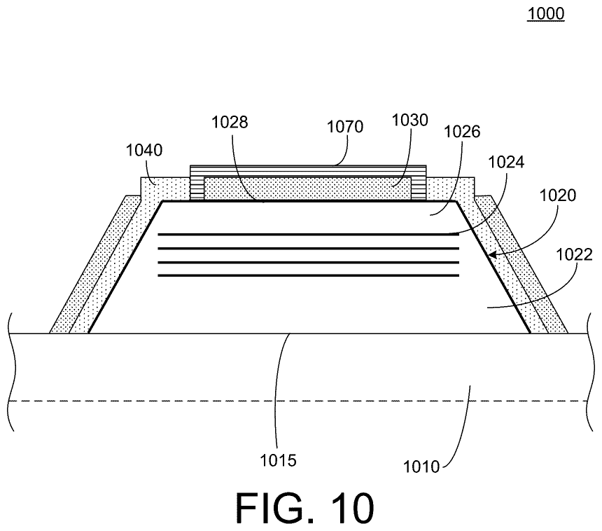

FIG. 10 is a diagram (e.g., a cross-sectional view) illustrating an example of a microLED 1000 that includes an Ag-based contact 1030 encapsulated by a barrier layer 1070, that further includes a gettering-passivation layer 1040, such as those described herein, that is disposed on sidewalls and a portion of an upper surface of a microLED mesa 1020 of the microLED 1000 As with the microLED 100 of FIG. 1, the microLED 1000 in FIG. 10 includes a buffer layer 1010 (e.g., a gallium nitride (GaN) buffer layer) having a growth interface surface 1015, e.g., for epitaxial growth of the microLED mesa 1020. As shown in FIG. 10, as with the microLED 100, the microLED mesa 1020 of the microLED 1000 includes at least one n-doped layer 1022, an active region 1024 (active QW region), and at least one p-doped layer 1026. In this example, the microLED mesa 1020 has sidewalls that are slanted or sloped. In some implementations, a microLED can have sidewalls that are vertical, and/or have other shapes. As shown in FIG. 10, the microLED mesa 1020 has a p-doped top (upper) surface 1028 (e.g., p-type GaN) on which the contact metal stack is formed, and a portion of the gettering-passivation layer 1040 is disposed.

In example implementations of the structures of FIGS. 8 to 10, a barrier layer (e.g., the barrier layer 870, the barrier layer 970, and/or the barrier layer 1070) may have at least one of the following properties or attributes. A barrier layer can be conductive. For instance, a barrier layer can have a resistivity that is less than 10⁻³ Ω·cm (less than 10⁻⁴ Ω·cm, less than 10⁻⁵ Ω·cm, or less than 10⁻⁶ Ω·cm), or have a resistance of less than 10⁵ Ω (less than 10⁴Ω, or less than 10³Ω). A barrier layer can have a metallic behavior. A barrier layer can include, or contain nitrogen. A barrier layer can be a metal-nitrogen compound. The metal can be one of titanium (Ti), magnesium (Mg), cobalt (Co), tantalum (Ta), or tungsten (W), with a respective metal-nitrogen formula of TiN, MgN, CoN, TaN or WN. For instance, possible chemical compositions for a barrier layer can include titanium nitride (such as TiN), magnesium nitride (such as Mg₃N₂), cobalt nitride (such as Co₃N₂, or Co(NO₃)₃), tantalum nitride (such as TaN, Ta₂N), or tungsten nitride (such as W₃N). In some implementations, a stoichiometry and/or phase of a material for a barrier layer may be selected to impart a desired resistivity. Accordingly, in some implementation, an exact stoichiometry of a barrier layer material may differ from those compounds listed above. A barrier layer material may be inhomogeneous. It may contain regions that are efficient at gettering hydrogen, such as islands/clusters of nitrogen-rich material, and/or regions that are efficient at gettering oxygen, such as regions of materials described herein, e.g., embedded in a matrix.

In the structures illustrated in FIGS. 8 to 10, an example of a contact stack, including an underlying semiconductor material or structure can be, in sequence of the stack, a heavily doped p-type GaN surface/an Ag-based contact layer/a metal_1 layer, a barrier layer, and a metal_2 layer. The Ag-based contact layer can be a Ag-contact layer, as described herein. That is, the Ag-contact layer can be a region that is predominantly composed of Ag. The region may include small amounts of other materials, such as a thin (less than 5 nm) interface (e.g., Ni) layer or a thin (e.g., Ni) layer embedded in an Ag matrix. The barrier layer can be a barrier layer, as described herein. The metal_1 layer can be a first metallic material stack, and the metal_2 layer can be a second metallic material stack. In some implementations, the metal_1 layer and the metal_2 layer can each include at least one layers of metal including Ti, Ni, Au, Pt, Al, W, Cr, and/or alloys thereof. In some implementations, compositions of the metal_1 layer and the metal_2 layer may be selected to improve adhesion, reduce strain, to act as diffusion barriers, achieve a desired resistance, etc.

In some implementations, variations of the contact stack are possible. For instance, an electrical contact with a p-type GaN material can be made with a metal other than Ag, or with a stack such as an ITO/Ag stack, an ITO/Al stack, or a stack including other transparent conductive oxides. In some implementations, the metal_1 layer and/or the metal_2 layer may be omitted. Additional layers (e.g., metal layers) may be formed on top of the stack, such as a copper (Cu) layer and other layers required for a damascene process, or for hybrid bonding of a corresponding microLED to a backplane. In some implementations, a contact stack can be formed using at least one of e-beam evaporation, sputtering, atomic layer deposition, or thermal deposition.

In some implementations, a barrier layer has a high density, or a density of an element (e.g. nitrogen) sufficient to block a diffusion path of hydrogen and/or oxygen. In some examples, the barrier layer is deposited by a technique that facilitates a high density, such as sputtering or ALD. Surrounding layers may be deposited by another technique, e.g., e-beam evaporation. In some implementations, a barrier layer can have a thickness of greater than 1 nm, 5 nm, 10 nm, 50 nm, or 100 nm).

An LED including a barrier layer can be produced, in some implementations, by the method 600 of FIG. 6, or variations of the method 600. For instance, formation of a barrier layer can be performed after forming a metallic contact at block 640 of the method 600. The method 600 may also include, at block 640, operations for forming a metal_1 layer and/or a metal_2. For instance, in one example, the metal_1 layer can be formed prior to forming the barrier layer, and the metal_2 layer can be formed after forming the barrier layer. That is, the operation of block 640 can include forming a metallic contact stack, such the examples in FIGS. 8 to 10. Furthermore, depending on the particular implementation, the passivation layer formed at block 630 can be a gettering passivation layer, or other passivation layer. In some implementations, that passivation layer can be formed after formation of a contact stack, e.g., the operations of block 630 and 640 can be reversed. In some implementations, for devices including a barrier layer, the thermal processing operation of block 650 of the method 600 can be a processing operation is performed in the presence of hydrogen and/or oxygen (e.g., hydrogen and/or oxygen that is diffused from a device being produced, and/or present in an ambient environment of the processing operation). For instance, the thermal processing operation can include at least one of a clean operation (e.g., a chemical clean), a descum operation, an anneal operation (e.g. in an rapid-thermal anneal (RTA) chamber), an etch operation, or a material deposition operation, as some examples.

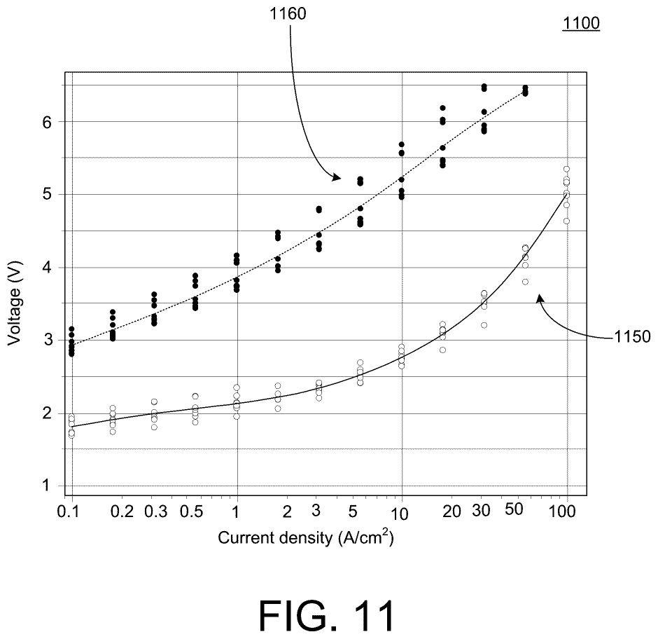

FIG. 11 is a graph 1100 illustrating experimental data demonstrating benefits of using a barrier layer in a microLED. The experimental data was collected from microLEDs produced on two separate semiconductor wafers. A first wafer, corresponding with a curve-fitted data set 1160, included microLEDs having contact metal stacks without barrier layers (and without a gettering-passivation layer). A second wafer, corresponding with a curve-fitted data set 1150, included microLEDs having contact metal stacks with barrier layers, such as those described herein, and without a gettering-passivation layer. In FIG. 11, the symbols (dots) indicate measurements for several devices, and the curves are fit to this data. Both wafers were subjected to a processing operation where SiOx was deposited on the micro-LEDs using a tetraethoxysilane (TEOS) precursor. Hydrogen released in this process can migrate through materials, including metal stacks, and may passivate a p+ GaN surface, leading to a high contact resistance. The experimental results illustrated in FIG. 11 where collected by operating respective microLEDs with an electrical power, such that a light emitting region of the LED emits light. For the microLED devices corresponding with the curve-fitted data set 1150, their barrier layer, during their operation, facilitates stable operation of the LED, such as described herein.

The curve-fitted data set 1150 and the curve-fitted data set 1160 shown in FIG. 11 illustrate current-voltage characteristics of the respective microLEDs. For the wafer corresponding with the curve-fitted data set 1160 (no barrier layer), hydrogen diffuses through the metal stack and the operating voltage for a given operating current density is relatively high (e.g., greater than 5 V at an operating current density of 10 A/cm²). For the wafer corresponding with the curve-fitted data set 1150 (including a barrier layer), the barrier layer reduces diffusion of hydrogen, resulting in an operating voltage of less than 3 V at an operating current density of 10 A/cm².

In this example, the wafer corresponding with the curve-fitted data set 1150 in FIG. 11 is an example of a wafer with a silver-based p-contact and a barrier layer, which retains a low operating voltage after a TEOS process step. In some implementations, a TEOS-based deposition process may be used to deposit a silicon oxide layer (e.g., a conformal layer) in preparation for a hybrid bonding process for coupling (attaching, etc.) a micro-LED array to a backplane, such as to form a micro-LED display. The TEOS-based deposition may form a layer with a thickness of at least 100 nm, or at least 1 μm.

In some implementations, processing operations (e.g., semiconductor manufacturing operations, etc.) can introduce a substantial amount of hydrogen and/or oxygen. Examples of such process operations can include deposition of a material in a hydrogen and/or oxygen-containing ambient, deposition of a material with hydrogen-containing and/or oxygen-containing precursors, annealing in a hydrogen-containing and/or oxygen-containing ambient, a high-temperature operation (e.g., greater than 300° C., greater than 400° C., or greater than 500° C.) in a hydrogen-containing and/or oxygen-containing ambient. In some implementations, a conductive barrier layer can be configured such that a flow of the hydrogen to a p-surface of a corresponding LED mesa during a processing operation is less than 10¹³ cm⁻². For instance, the conductive barrier layer can be configured (e.g., have a composition and/or density) such that an additional hydrogen concentration, as a result of diffusion hydrogen during the processing operation, proximate the p-surface after the processing operation is less than 10¹⁹ cm⁻³.

It can be desirable to limit the diffusion of hydrogen and/or oxygen towards or semiconductor material, and/or associated interfaces (e.g. interfaces with a conductive layer, semiconductor material, or insulating layer). Such diffusion can, in some implementations, be limited by a use of a passivation material (covering a portion of the LED sidewalls), such as those described herein, where the passivation material acts as a hydrogen barrier/getter and/or as an oxygen barrier/getter. In some implementations, a barrier layer or material, such as those described herein (e.g., in a metal contact) can be used, where the barrier material acts as a hydrogen barrier/getter and/or as an oxygen barrier/getter.

In some implementations, passivation materials can include materials such as those described herein, as well as other materials. For instance, in some implementations, passivation materials can include at least one of BeN, BeAlN, BeBN, BeO, CaN, CaAlN, CaBN, CaO, MgN, MgAlN, MgBN, MgO, SiN, SiOx, SiAlN, AlOx, SiOxNy, SiCxNy, and/or compounds based on Group II-nitrides (where x and y represent stoichiometric values). In some implementations, a passivation material can be a composition of different materials, e.g., including the materials described herein. For instance, such passivation materials can be a compound (mixture) of materials, or a layered stack with multiple materials. For instance, in some implementations, a passivation material may have a layer of AlOx, and a layer of one or more of BeN, BeAlN, BeBN, BeO, CaN, CaAlN, CaBN, CaO, MgN, MgAlN, MgBN, MgO, SiN, SiOx, SiAlN, SiOxNy, or SiCxNy.

In some implementations, a passivation material may electrically insulating. For instance, a passivation material can have a resistivity of at least 10⁴ Ω·cm (at least 10⁶ Ω·cm, or at least 10⁸ Ω·cm). A passivation material may have an area greater than 10⁻¹² m² (e.g., at least 1 um²), or less than 10⁻¹⁰ m² (e.g., less than 10 um²), or in a range 10⁻¹² to 10⁻¹⁰ m². In some implementations, a passivation material may have a thickness of at least 0.5 nm (at least 1 nm, at least 5 nm, at least 10 nm, at least 50 nm, at least 100 nm, at least 500 nm), or a thickness in a range 1-100 nm, or in a range or 10-1000 nm. In some implementations, a passivation material may be characterized by a resistance of at least 10⁷Ω (at least 10⁸Ω, at least 10⁹Ω, or at least 10¹⁰Ω). A passivation material may conduct a current of less than 10 nanoamps (nA), less than 1 nA, or less than 0.1 nA during operation of an LED.

In example implementations, both the optical benefits and electrical benefits of the approaches described herein (e.g., use of a gettering passivation layer and/or use of a barrier layer in a contact metal stack) can be achieved in an electronic device, such as a microLED. Accordingly, an LED (e.g., a microLED) can have (include) one or more of the following properties or features alone or in combination. In some implementations, an LED can have a size (lateral dimension) of less than 20 μm (less than 10 μm, less than 5 μm, less than 3 μm, less than 2 μm, less than 1.5 μm, or less than 1 μm). In some implementations, an LED can have a wall-plug efficiency of at least 1% (at least 3%, at least 5%, at least 10%, or at least 20%) at a current density of at least 0.1 A/cm² (at least 1 A/cm², or at least 10 A/cm²). In some implementations, an LED can operate with a wavelength of at least 400 nm (at least 500 nm, or at least 600 nm).

In some implementations, a high-temperature operation refers to an operation that occurs, or is performed at a temperature significantly above room temperature, e.g., 100° C. above room temperature, or more. In some implementations, the high-temperature operation may occur at a temperature above 1500 C, 200° C., 3000 C, 400° C., or 500° C.

In some implementations, for a microLED, a lateral dimension may be defined as the side dimension of a square LED; the diameter of a circular LED; or more generally, a typical dimension characterizing the lateral extent of the LED.

Implementations described herein provide a number of benefits. For instance, the described implementations provide a stable electrical passivation (with low voltage and without hysteresis, as seen in, for example, FIG. 7) together with a stable optical behavior for an Ag-based reflector (as seen in, for example, FIG. 3). This is contrasted with other materials, which cannot simultaneously provide, at least, these two benefits.

In some implementations, maintaining good electrical and optical performance can become increasingly difficult for LEDs as their dimensions decrease. Indeed, in a device (microLED) of small dimensions, such as described herein, impurities that diffuse over short distances may cause degradation (electrical and/or optical) of a reflector. Likewise, larger perimeter-to-area ratios of small devices may make them more sensitive to charge traps, causing operating instability. In some cases, this may cause an undesirable cliff in performance below a certain size, e.g., less than 10 μm, or less than 5 μm. Implementations described herein provide for a benefit of facilitating good electrical and optical performance for very small devices, e.g., less than 2 μm, or even less than 1 μm.

In some implementations, an LED with a barrier layer and/or a getting-passivation layer can have an operating voltage of less than 5V (less than 4 V, less than 3.5V, or less than 3V) after a process operation, such a TEOS-based deposition, where the process operation is performed in the presence of hydrogen (and/or oxygen). The process operation can be performed at a temperature of at least 200° C. (at least 300° C., at least 400° C., or at least 500° C.). In some implementations, a microLED display implemented with microLEDs including a barrier layer and/or a gettering-passivation layer can have LED operating voltages of less than 5 V (less than 4 V, less than 3.5V, or less than 3 V) or less than an energy of emitted photons (e.g., in electron-volts) plus 2 V (plus 1.5 V, plus 1 V, or plus 0.5V), where the operating voltages are measured at an operating current density of at least 10 A/cm²; or at a current of at least 100 nA, or at least 1 μA).

Implementations include semiconductor mesas having an n-doped region, an active region (e.g. a quantum well light emitting region), a p-region terminated by a p-surface. The mesas may be formed on a template, e.g., its bottom region, or surface may be in direct contact with the template. The p-surface may coincide with a top surface of the mesa, or the p-surface may be a region surrounding the mesa, in which case a p-region can be an outer region of the mesa (e.g. including a top portion and sidewall regions).

In a general aspect, an electronic device include a semiconductor structure including a doped surface, a silver-based (Ag-based) layer electrically contacting at least a portion of the doped surface and a passivation layer disposed on a portion of the semiconductor structure. A portion of the passivation layer is in physical contact with the Ag-based layer. The passivation layer is a material compound including a II-Nitride material.

Implementations can include one or more of the following features or aspects, alone or in combination. For example, the doped surface can be at least one of a top surface of the semiconductor structure, or a surface of an epitaxial layer.

The semiconductor structure can include a sidewall surface. At least a portion of the passivation layer can be disposed on the sidewall surface.

A first portion of the Ag-based layer can be disposed on the doped surface. A second portion of the Ag-based layer can be disposed on the passivation layer.

The electronic device can have a lateral dimension of less than or equal to 10 micrometers (μm).

The semiconductor structure can include a III-Nitride material.

The II-Nitride material can include at least one of magnesium nitride, calcium nitride, or beryllium nitride.

The material compound can include a Group III element.

The passivation layer can include, by composition, at least ninety percent of the II-Nitride material.

The semiconductor structure can include a layer including gallium nitride (GaN), and a light-emitting layer including indium gallium nitride (InGaN).

The electronic device can be a light-emitting diode (LED). The LED can include a mesa with a top surface, a sidewall, and a base. The passivation layer can cover a portion of the top surface and a portion of the sidewall.

An interface of the Ag-based layer and the doped surface can have a reflectivity greater than ninety percent for light with a wavelength in a range of 450 to 650 nanometers (nm).

The passivation layer can have a refractive index greater than 1.7 for light with a wavelength in a range of 450 to 650 nanometers (nm).

The passivation layer can be configured to getter at least one of oxygen, or hydrogen.

The passivation layer can be configured to trap mobile charges.

In another general aspect a micro-light-emitting diode (microLED) includes a semiconductor structure having a doped surface; and a light-emitting region. The microLED also includes a metal-based layer electrically contacting at least a portion of the doped surface, and a passivation layer disposed on the semiconductor structure. A portion of the passivation layer is in physical contact with the metal-based layer. The passivation layer is a compound including a II-nitride material. The microLED has a lateral dimension of less than or equal to 10 micrometers (μm).

Implementations can include one or more of the following features or aspects, alone or in combination. For example, the metal-based layer can be an Ag-based layer. A first portion of the Ag-based layer can be disposed on the doped surface. A second portion of the Ag-based layer can be disposed on the passivation layer.

The semiconductor structure can include a III-Nitride material.

The II-Nitride material can include at least one of magnesium nitride, calcium nitride, or beryllium nitride.

The compound can further include a Group III element.

The passivation layer can include, by composition, at least ninety percent of the II-Nitride material.

The semiconductor structure can include a layer including gallium nitride (GaN), and a light-emitting layer including indium gallium nitride.

An interface of the metal-based layer and the doped surface can have a reflectivity greater than ninety percent for light with a wavelength in a range of 450 to 650 nm.

The passivation layer can have a refractive index higher than 1.7 for light with a wavelength in a range of 450 to 650 nm.

The passivation layer can be configured to getter at least one of oxygen, or hydrogen.

The passivation layer can be configured to trap mobile charges.

In another general aspect an LED includes a semiconductor structure having a doped surface and a light-emitting region, a silver-based (Ag-based) layer electrically contacting at least a portion of the doped surface; and a passivation layer formed on a surface of the semiconductor structure. A portion of the passivation layer is in physical contact with the Ag-based layer. The passivation layer includes a chemical element X with a formation enthalpy for an oxide XO of greater than 500 kilo-joules per mole.

Implementations can include one or more of the following features or aspects, alone or in combination. For example, the passivation layer can include a compound of X and nitrogen.

A first portion of the Ag-based layer can be disposed on the doped surface. A second portion of the Ag-based layer can be disposed on the passivation layer.

The LED can have a lateral dimension of less than or equal to 10 μm.

The semiconductor structure can include a III-Nitride material.

X can be a Group II element.

The passivation layer can include a Group III element.

The passivation layer can include, by composition, at least ten percent of X.

The semiconductor structure can include a layer including gallium nitride (GaN), and a light-emitting layer including indium gallium nitride (InGaN).

An interface of the Ag-based layer and the doped surface can have a reflectivity greater than ninety percent for light with a wavelength in a range of 450 to 650 nm.

The passivation layer has a refractive index greater than 1.7 for light with a wavelength in a range of 450 to 650 nanometers nm.

The passivation layer can be configured to getter at least one of oxygen, or hydrogen.

The passivation layer can be configured to trap mobile charges.

In another general aspect, a method for producing a light-emitting diode (LED) includes forming a silver-based (Ag-based) layer on a doped surface of a semiconductor structure including a light emitting region. The Ag-based layer electrically contacts the doped surface. The method also includes forming a dielectric layer on the semiconductor structure. The dielectric layer is proximate the Ag-based layer. After forming the Ag-based layer and the dielectric layer, the method includes performing a thermal processing operation on the semiconductor structure, where the dielectric layer is configured to maintain a reflectivity of the Ag-based layer of greater than or equal to 80% for light at a wavelength of 500 nm after the thermal processing operation.

Implementations can include one or more of the following features or aspects, alone or in combination. For example, the dielectric layer can include a group II-nitride material.

The dielectric layer can include a chemical element X with a formation enthalpy for an oxide XO of greater than 500 kilo-joules per mole.

The thermal processing operation can be performed, at least in part, at a temperature of greater than or equal to 3000 Celsius (C).

The thermal processing operation can be one of an annealing operation for the Ag-based layer, a semiconductor doping activation operation, a metal reflow operation, or a metal bonding operation.

Maintaining the reflectivity can include the dielectric layer gettering at least one of hydrogen or oxygen during the thermal processing operation.

The dielectric layer can trap mobile charges.

Forming the dielectric layer can include forming the dielectric layer such that at least a portion of the dielectric layer is in physical contact with the Ag-based layer.

A chemical species can be present during the thermal processing operation. The dielectric layer can getter the chemical species. The chemical species can be one of oxygen or hydrogen.

In another general aspect, for a light emitting diode (LED) having a semiconductor structure with a doped surface and a light-emitting region, a silver-based (Ag-based) layer electrically contacting at least a portion of the doped surface, a dielectric passivation layer including a II-Nitride material formed on a surface of the semiconductor structure with a portion of the dielectric passivation layer being in physical contact with the Ag-based layer, a method of operating includes operating the LED with an electrical power, such that a light emitting region of the LED emits light. The dielectric passivation layer is configured, during the operating, to facilitate stable operation of the LED.

Implementations can include one or more of the following features or aspects, alone or in combination. For example, facilitating stable operation of the LED can include the dielectric passivation layer trapping mobile charges.

Stable operation of the LED can be characterized by a substantially constant light output of the LED over time.

Stable operation of the LED can be characterized by an amount of hysteresis of a current-voltage characteristic of the LED being below a threshold value. The threshold value, at an operating current of the LED, can be 50 millivolts. The operating current can correspond to a current density of greater than 1 amp per centimeter-squared in the light-emitting region.

The LED can have a lateral dimension of less than 10 micrometers.

The Ag-based layer can have a reflectivity of greater than or equal to 90% for light emitted by the light-emitting region at a wavelength of 500 nanometers.

In another general aspect, a method for producing a light-emitting diode (LED) includes forming a semiconductor LED mesa, forming a protective layer on the semiconductor LED mesa, forming a metal contact on the semiconductor LED mesa, and performing a processing operation on the LED. The processing operation causes a release of a species, The protective layer is configured to reduce diffusion of the species towards the semiconductor LED mesa.

Implementations can include one or more of the following features or aspects, alone or in combination. For example, the species can be oxygen or hydrogen.

The semiconductor LED mesa can have a sidewall, and the protective layer can cover a portion of the sidewall.

The protective layer can getter the species.

The protective layer can include a chemical element X that reacts with the species to form one of an oxide XO, or a hydride XH.

The protective layer can act as a diffusion barrier for the species.

The protective layer can have a thickness of at least 5 nm.

The protective layer can trap mobile charges.

The metal contact can be an Ag-based contact.

The protective layer can be in direct contact with the Ag-based contact, and can cause the Ag-based contact to maintain a high reflectivity during the processing operation.

The protective layer can reduce diffusion of the species towards the Ag-based contact.

In another general aspect, a light-emitting diode (LED) includes a semiconductor mesa having an n-doped region; an active region; and a p-doped region terminated by a p-surface. The LED also includes a p-contact disposed on a portion of the p-surface. The p-contact includes an Ag-based layer electrically contacting the p-surface, and a metal stack that encapsulates the Ag-based layer. The metal stack includes at least one layer of a conductive compound including a metal and nitrogen.

Implementations can include one or more of the following features or aspects, alone or in combination. For example, the conductive compound can act as a diffusion barrier for hydrogen.

The metal can include one of titanium, magnesium, cobalt, tantalum, or tungsten.

The conductive compound can include one of titanium nitride, magnesium nitride, cobalt nitride, tantalum nitride, or tungsten nitride.

The conductive compound can have a resistivity less than 1e⁻³ ohm·cm.

The at least one layer of conductive compound can have a resistance less than 10⁵ ohms.

The metal stack can include a first metal disposed between the Ag-based layer and the conductive compound, and a second metal disposed the conductive compound opposite the Ag-based layer.

The Ag-based layer can be in direct contact with the p-surface.

A transparent oxide can be disposed between the Ag-based layer and the p-surface.

The LED can have a first hydrogen concentration in the Ag-based layer and a second hydrogen concentration on a side of the at least one layer of the conductive compound opposite the Ag-based layer. The second hydrogen concentration can be at least ten times the first hydrogen concentration.

In another general aspect, a light-emitting diode (LED) includes a semiconductor mesa having an n-doped region, a light-emitting region, a p-doped region terminated by a p-surface, and at least one sidewall. The LED also includes a p-contact formed on a portion of the p-surface. The p-contact includes at least one layer of a conductive compound including a first metal and nitrogen. The LED further includes a passivation layer formed on a portion of the at least one sidewall. The passivation layer includes at least one layer of an insulating compound including a second metal and nitrogen.

Implementations can include one or more of the following features or aspects, alone or in combination. For example, the conductive compound can act as a diffusion barrier for hydrogen.

The first metal can include one of titanium, magnesium, cobalt, tantalum, or tungsten.

The conductive compound can include one of titanium nitride, magnesium nitride, cobalt nitride, tantalum nitride, or tungsten nitride.

The conductive compound can have a resistivity less than 1e⁻³ ohm·cm.

The at least one layer of the conductive compound has a resistance less than 10⁵ ohms.

The LED can include a third metal disposed between the p-contact and the conductive compound, and a fourth metal disposed on the conductive compound opposite the p-contact.

The second metal can include one of magnesium, calcium, or beryllium.

The insulating compound can include one of magnesium nitride, calcium nitride, or beryllium nitride.

In another general aspect, a method for producing an LED includes forming a p-contact in direct contact with a p-surface of an LED semiconductor mesa, and forming a metal stack on the p-contact, where the metal stack has a conductive barrier layer. The method also includes performing a processing operation on the LED. The processing operation uses, or causes a release of hydrogen. The conductive barrier layer is configured to reduce diffusion of the hydrogen through the p-contact to the p-surface during the processing operation.

Implementations can include one or more of the following features or aspects, alone or in combination. For example, the p-contact can be Ag-based.

The conductive barrier layer can be configured such that a flow of the hydrogen to the p-surface during the processing operation is less than 10¹³ cm-2.

The conductive barrier layer can be configured such that an additional hydrogen concentration, as a result of diffusion hydrogen during the processing operation, proximate the p-surface after the processing operation is less than 10¹⁹ cm⁻³.

The processing operation can include depositing silicon oxide deposition using a TEOS precursor.

The processing operation can occur at a temperature above 300° C.

The p-contact can have a specific contact resistance that is less than 1e⁻⁴ ohm cm² after the processing operation.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Implementations of the various techniques described herein may be implemented in (e.g., included in) digital electronic circuitry, or in computer hardware, firmware, software, or in combinations of them. Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An electronic device comprising:
a semiconductor structure including a doped surface;
a silver-based (Ag-based) layer electrically contacting at least a portion of the doped surface; and
a passivation layer disposed on a portion of the semiconductor structure,
a portion of the passivation layer being in physical contact with the Ag-based layer, and
the passivation layer being a material compound including a II-Nitride material.

2. The electronic device of claim 1, wherein the doped surface is at least one of:
a top surface of the semiconductor structure; or
a surface of an epitaxial layer.

3. The electronic device of claim 1, wherein:
the semiconductor structure includes a sidewall surface; and
at least a portion of the passivation layer is disposed on the sidewall surface.

4. The electronic device of claim 1, wherein:
a first portion of the Ag-based layer is disposed on the doped surface; and
a second portion of the Ag-based layer is disposed on the passivation layer.

5. The electronic device of claim 1, wherein the electronic device has a lateral dimension of less than or equal to 10 micrometers (μm).

6. The electronic device of claim 1, wherein the semiconductor structure comprises a III-Nitride material.

7. The electronic device of claim 1, wherein the II-Nitride material includes at least one of: magnesium nitride, calcium nitride, or beryllium nitride.

8. The electronic device of claim 1, wherein the material compound further includes a Group III element.

9. The electronic device of claim 1, wherein the passivation layer includes, by composition, at least ninety percent of the II-Nitride material.

10. The electronic device of claim 1, wherein the semiconductor structure includes:
a layer including gallium nitride (GaN); and
a light-emitting layer including indium gallium nitride (InGaN).

11. The electronic device of claim 10, wherein the electronic device is a light-emitting diode (LED).

12. The LED of claim 11, wherein the LED comprises a mesa with a top surface, a sidewall, and a base, and the passivation layer covers a portion of the top surface and a portion of the sidewall.

13. The electronic device of claim 1, wherein an interface of the Ag-based layer and the doped surface has a reflectivity greater than ninety percent for light with a wavelength in a range of 450 to 650 nanometers (nm).

14. The electronic device of claim 1, wherein the passivation layer has a refractive index greater than 1.7 for light with a wavelength in a range of 450 to 650 nanometers (nm).

15. The electronic device of claim 1, wherein the passivation layer is configured to getter at least one of oxygen, or hydrogen.

16. The electronic device of claim 1, wherein the passivation layer is configured to trap mobile charges.

17. A micro-light-emitting diode (microLED) comprising:
a semiconductor structure having:
a doped surface; and
a light-emitting region;
a metal-based layer electrically contacting at least a portion of the doped surface; and
a passivation layer disposed on the semiconductor structure,
a portion of the passivation layer being in physical contact with the metal-based layer,
the passivation layer is a compound including a II-nitride material, and
the microLED has a lateral dimension of less than or equal to 10 micrometers (μm).

18. The microLED of claim 17, wherein the II-Nitride material includes at least one of: magnesium nitride, calcium nitride, or beryllium nitride.

19. The microLED of claim 17, wherein the compound further comprises a Group III element.

20. The microLED of claim 17, wherein the passivation layer includes, by composition, at least ninety percent of the II-Nitride material.

21. The microLED of claim 17, wherein an interface of the metal-based layer and the doped surface has a reflectivity greater than ninety percent for light with a wavelength in a range of 450 to 650 nanometers (nm).

22. The microLED of claim 17, wherein the passivation layer is configured to:
getter at least one of oxygen, or hydrogen; and
trap mobile charges.

23. An LED comprising:
a semiconductor structure including a doped surface and a light-emitting region;
a silver-based (Ag-based) layer electrically contacting at least a portion of the doped surface; and
a passivation layer formed on a surface of the semiconductor structure,
a portion of the passivation layer being in physical contact with the Ag-based layer, and
the passivation layer including a chemical element X with a formation enthalpy for an oxide XO of greater than 500 kilo-joules per mole.

24. The LED of claim 23, wherein the passivation layer includes a compound of X and nitrogen.

25. The LED of claim 23, wherein X is a Group II element.

26. The LED of claim 23, wherein the passivation layer further comprises a Group III element.

27. The LED of claim 23, wherein the passivation layer includes, by composition, at least ten percent of X.

28. The LED of claim 23, wherein an interface of the Ag-based layer and the doped surface has a reflectivity greater than ninety percent for light with a wavelength in a range of 450 to 650 nanometers (nm).

29. The LED of claim 23, wherein the passivation layer has a refractive index greater than 1.7 for light with a wavelength in a range of 450 to 650 nanometers (nm).

30. The LED of claim 23, wherein the passivation layer:
getters at least one of oxygen, or hydrogen; and
traps mobile charges.
